(19) United States
(12) Patent Application Publication
(10) Pub. No.: US 2014/0145786 A1
(43) Pub. Date: May 29, 2014

(54) SYSTEM FOR AMPLIFYING A COMMON RF ENERGY SIGNAL AND SWITCHING THE AMPLIFIED SIGNAL BETWEEN ONE OF TWO OUTPUTS

(71) Applicant: Delta-Sigma Inc., Riverside, CA (US)

(72) Inventor: Ernesto G.F. Starri, Riverside, CA (US)

(21) Appl. No.: 13/921,795

(22) Filed: Jun. 19, 2013

Related U.S. Application Data
(60) Provisional application No. 61/730,621, filed on Nov. 28, 2012.

(51) Int. Cl. H03F 1/00

(52) U.S. Cl. CPC H03F 1/00
USPC 330/117

(57) ABSTRACT

A RF input signal system and method switches the RF input signal amplified by an amplifier PA1 or PA2 to be present only in great magnitude at the summing port of a hybrid combiner H2 when the SPDT switch SW1 is directing the “RF in” signal to the summing port of the hybrid divider H1, while the balancing port of H1 is terminated by the switch SW1. The benefit of switching between H and V ports by using this method eliminates the insertion losses of the switch SW1 and isolators ISO1 and ISO2 of the prior art. The benefit is also the speed of switching which can now be executed much faster (in nanoseconds) in comparison to the method shown in FIG. 1 where the limiting factor are the PIN diodes used in such devices (SW1 of FIG. 1) that only allows switching transients in tens of microseconds only. The non-summing port of H2 is then only radiating much less energy of −20 to −30 dB below that of the summing port.

### CROSS-REFERENCE TO RELATED APPLICATIONS

This application claims the benefit of U.S. Provisional Application Ser. No. 61/730,621 for “SYSTEM FOR AMPLIFYING A COMMON RF ENERGY SIGNAL AND SWITCHING THE AMPLIFIED SIGNAL BETWEEN ONE OF TWO OUTPUTS” filed Nov. 28, 2012 of which is incorporated fully herein by reference.

### TECHNICAL FIELD

The present invention relates to antenna systems and more particularly, relates to a system that amplifies a common RF energy source and switches the amplified signal between two outputs, as one exemplary embodiment were in the two outputs mentioned herein are defined for transmission purposes as vertically polarized and horizontally polarized antennas, or linear or orthogonal combinations of these two eg. circular polarizations. This will enable receiving from the non-transmitting port ANT1 or from ANT2 without the need for a circulator in the receiving path.

### BACKGROUND INFORMATION

An antenna is a transducer that converts radio frequency (RF) electric current to electromagnetic waves that are then radiated into space.

An antenna can radiate with the plane of polarization fixed (such as one of the linear polarizations), or rotating (such as one of the circular polarizations). This provides for identical or orthogonal polarizations and cross polarization processing within the received channel which are of interest in certain radar target scattering problems.

The switching time between transmit and receive and the switching time between polarizations (and vice versa) have to be as fast as technically possible to detect targets that are in close proximity.

Several factors are to be considered for airborne RADAR applications. These include weight, size, and energy efficiency of the Radar system. Weight affects the capacity of duration of airborne time and together with energy efficiency the capacity of the aircraft to carry more fuel on board. The size limits the choice of aircraft being used. All of these above listed factors have to be taken into account in the design of the equipment.

The architecture currently being used have the following limitation: when using a switch and a circulator in the receiving path, the insertion loss between the receiving port and the receiving antenna can be as high as 2 dB especially when a large bandwidth must be used as in synthetic aperture radars (SAR). Adding more transmission energy to overcome the loss in the strength of the receiving echo is the only alternative to compensate this loss. Inevitably that means that as the transmitting power increases so does size, energy consumption and the weight; meaning less fuel and less airborne time. In addition the cost of equipment also increases. Thus a better method then what is generally currently implemented need improvement in the design architecture.

With reference to FIG. 1 which illustrates a representative prior art system, the Power Amplifier PA1 amplifies a signal present at the ‘RF in’ port. A single pole two way switch SW1 then selects the output path to be either the Isolator Iso1 or Iso2. During the transmission sequence, the amplified ‘RF in’ signal is then present at either ANT1 or ANT2 respectively and the SPDT switches SW2 and SW3 direct the isolation port of Iso1 and Iso2 to the terminating load. During the receiving sequence, the SPDT switches SW2 and SW3 direct the receiving path to the respective ports RX1 or RX2. The disadvantages of this architecture are as follows: the receiving signal is attenuated first by the isolation path of Iso1 and Iso2 and then by the insertion loss of SW2 and SW1. The insertion loss of SW1 and the insertion loss of Iso1 and Iso2 attenuate the transmitting path which is an undesirable result that must be compensated for.

Accordingly, what is needed is a system that allows radio frequency energy to be transmitted and/or received through one of either polarization or the other in a controlled manner with little insertion loss.

### BRIEF DESCRIPTION OF THE DRAWINGS

These and other features and advantages of the present invention will be better understood by reading the following detailed description, taken together with the drawings wherein:

FIG. 1 is a block diagram of the prior art radar signal switching methodology;

FIG. 2 is a block diagram of the radar transmitting signal switching system and method of the present invention; and

FIG. 3 is a schematic diagram of another embodiment of the invention that includes the signal switch method of FIGS. 2 and 3 along with a low loss receiving system and method.

### DETAILED DESCRIPTION OF THE PREFERRED EMBODIMENTS

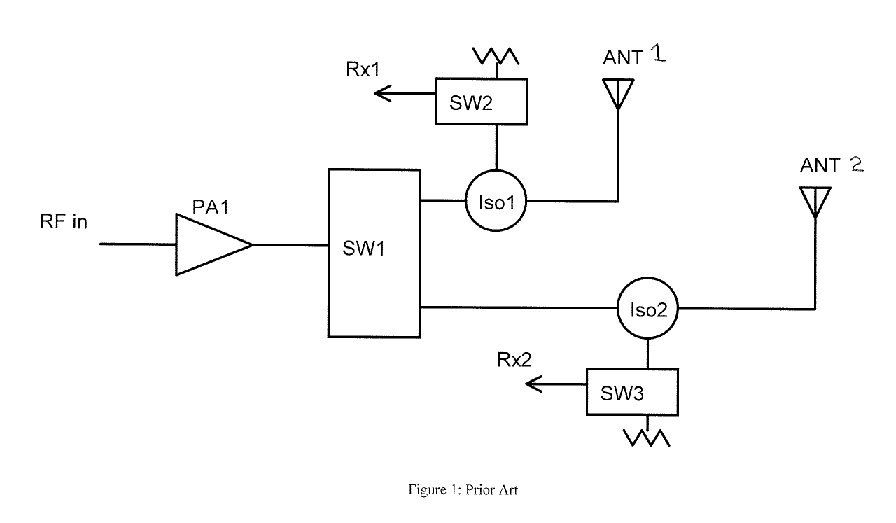

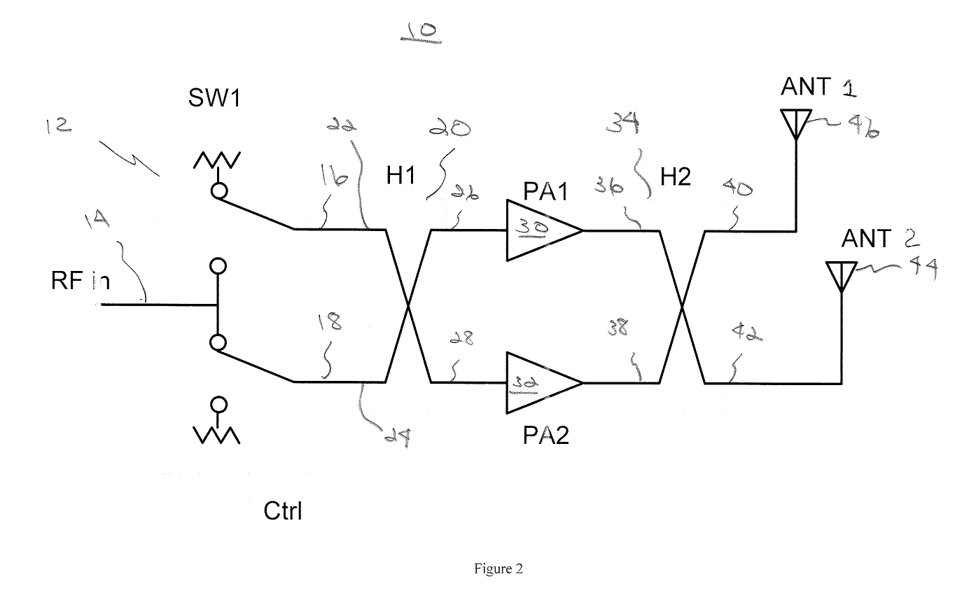

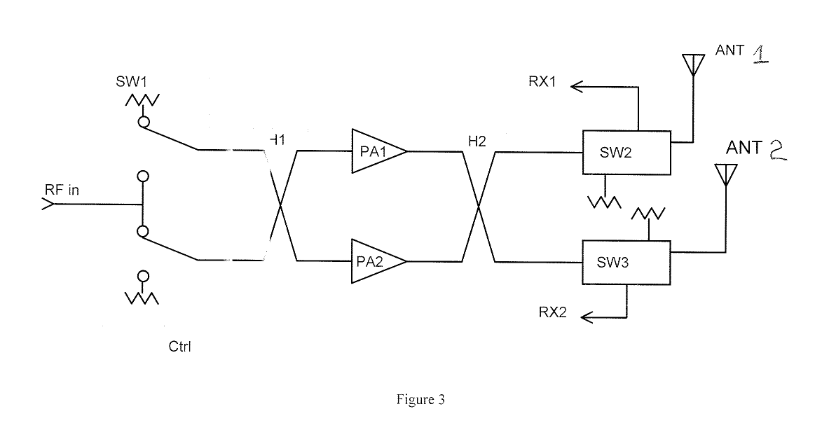

The present invention, which will be explained first in connection with FIG. 2, is directed to switching the RF input signal amplified by PA1 and PA2 to be present only in great magnitude at the selected summing port of the hybrid combiner H2 when SPDT switch SW1 is directing the “RF in” signal to the summing port of the hybrid divider H1 while the balancing port of H1 is terminated by the switch SW1. FIG. 2 shows a switching combination according to the present invention utilizing a SPDT switch SW1 wherein the amplified transmission signal is present at ANT1. The benefit of switching between ANT1 and ANT2 ports is that using this method eliminates the insertion losses of the switch SW1 and isolators Iso1 and Iso2 of prior art FIG. 1. The benefit is also the speed of switching which can now be executed much faster (in nanoseconds) in comparison to the method shown in FIG. 1 where the limiting factor are the PIN diodes used in such devices (SW1 of FIG. 1) that only allows switching transients in tens of microseconds only. The non-summing port of H2 is then only radiating much less energy of −20 to −30 dB below that of the summing port. However this port can be connected to a terminating load by SW2 as shown in FIG. 3.

The present invention features a system 10, FIG. 2, for amplifying a common rf energy source signal, and for switching the amplified RF signal between two outputs. A single pole double throw switch 12 has one input 14 and a first and second output 16, 18 respectively. The single pole double throw switch is configured for receiving, on the input 14 of the switch 12, an RF input signal, and operative in a first position (not shown) for providing the RF input signal on the first output 16, and operative in a second position (as shown) for providing the RF input signal on the second output 18.

A first hybrid divider (H1)20 is coupled to and responsive to the first and second outputs of the single pole double throw switch 12. The hybrid divider (H1) 20 including a summing port 22 and a balancing port 24. The hybrid divider (H1) 20 is configured for receiving the RF input signal from one of the first and second outputs on one of the summing port or the balancing port based on said position of the single pole double throw switch. The first hybrid divider includes first and second outputs 26, 28 coupled to first and second amplifiers 30, 32 respectively. The first hybrid divider 20 is operative for providing the RF input signal to one of said first and second amplifier based on the position of the single pole double throw switch.

A second hybrid divider 34 is provider after the first and second amplifiers 30, 32. The second Hybrid divider, of the same or similar type as the first hybrid divider 20, includes a summing input port 36 and a balancing input port 38. The second hybrid divider 34 is configured for receiving the amplified RF input signal from one of the first and second amplifiers 30, 32 on one of the summing port 36 and balancing port 38 based on the position of the single pole double throw switch 12. The second hybrid divider 34 also includes first and second outputs 40, 42 coupled to a vertically polarized antenna and a horizontally polarized antenna respectively. The second hybrid divider (H2)34 is configured for providing the amplified RF input signal 14 to one polarized antenna 44 and another polarized antenna 46, respectively, based on the position of the single pole double throw switch 12.

With reference to FIG. 3; the addition of SW2 and SW3 are key elements that enable the Reception of the signals present at ANT2 and ANT1 while the radar is in the receive sequence. During this sequence, both switches SW2 and SW3 are directing the signal flow only to the respective ports RX1 and RX2. The benefit of this architecture is that the only insertion loss in the receive paths are only the ones of SW2 and SW3 (of FIG. 3). In addition, after signal transmission on the ANTH port, the reception on the ANTH port RX2 is immediate and no delay is present. Thus very short target data acquisition can be obtained at the very moment the transmission sequence stops. The same applies when the transmission is done on the ANT2 path and reception is available immediately with no delay at the ANT2 RX1 port.

The invention as shown is not only applicable to radars where a controlled polarization is required but to radars where both antennas are not polarized.

Modifications and substitutions by one of ordinary skill in the art are considered to be within the scope of the present invention, which is not to be limited except by the allowed claims and their legal equivalents.

The invention claimed is:

1. A system for amplifying a common rf energy source signal, and for switching the amplified signal between two outputs, the system comprising:
a single pole double throw switch having one input and a first and second output, said single pole double throw switch configured for receiving, on said input of the switch, an RF input signal, and operative in a first position for providing said RF input signal on said first output and operative in a second position for providing said RF input signal on said second output; and
a first hybrid divider, coupled to and responsive to said first and second outputs of said single pole double throw switch, said hybrid divider including a summing port and a balancing port, said hybrid divider configured for receiving said RF input signal from one of said first and second outputs on one of said summing port and balancing port based on said position of said single pole double throw switch, said first hybrid divider including first and second outputs coupled to first and second amplifiers respectively, said first hybrid divider operative for providing said RF input signal to one of said first and second amplifier based on the position of said single pole double throw switch; and
a second hybrid divider, said second hybrid divider including a summing port and a balancing port, said hybrid divider configured for receiving said amplified RF input signal from one of said first and second amplifiers on one of said summing port and balancing port based on said position of said single pole double throw switch, said second hybrid divider including first and second outputs coupled to one polarized antenna and another different antenna respectively, said second hybrid divider configured for providing said amplified RF input signal to one of the first polarized antenna and a second polarized antenna based on the position of said single pole double throw switch.
